(19) United States
(12) Patent Application Publication
(10) Pub. No.: US 2006/0148237 A1
(43) Pub. Date: Jul. 6, 2006

(54) Method for fabricating a semiconductor device

(76) Inventor: Sung Ho Jang, Eumseong-gun (KR)

Correspondence Address: Song K. Jung;MCKENNA LONG & ALDRIDGE LLP, 1900 K Street, N.W., Washington, DC, 20006, US

(21) Appl. No.: 11/320,337

(22) Filed: Dec. 29, 2005

(30) Foreign Application Priority Data
Dec. 30, 2004 (KR) 10-2004-0117261

(51) Int. Cl. H01L 21/4763

(52) U.S. Cl. 438/626; 438/624; 438/623

(57) ABSTRACT

A method of fabricating a semiconductor device wherein the step difference of an insulating layer surface is effectively eliminated to completely planarize a surface of the insulating layer by DHF dipping treatment after completion of the insulating layer planarization.

### CROSS REFERENCE TO RELATED APPLICATION

This application claims the benefit of the Korean Patent Application No. 10-2004-0117261, filed on Dec. 30, 2004, which is hereby incorporated by reference for all purposes as if fully set forth herein.

### BACKGROUND OF THE INVENTION

1. Field of the Invention

The present invention relates to a method of fabricating a semiconductor device. Although the present invention is suitable for a wide scope of applications, it is particularly suitable for preventing a bridge between metal lines due to a step difference by completely planarizing a surface of an insulating layer by performing DHF surface treatment after completion of planarization of the insulating layer by CMP.

2. Discussion of the Related Art

Generally, to meet the demands for size reduction, high capacity and high integration, a semiconductor device needs a mandatory process for forming multi-layer lines such as metal lines to electrically connect devices after completion of transistors, bitlines, capacitors and the like.

In particular, an insulating interlayer is formed over a semiconductor substrate including a device sublayer having transistors, bitlines and capacitors. The insulating interlayer is planarized by CMP. A metal line is formed on the planarized insulating interlayer and is then electrically connected to a device sublayer via a contact.

A method of fabricating a semiconductor device according to a related art is explained with reference to the attached drawings as follows.

FIGS. 1A to 1C are cross-sectional diagrams of a device fabricated by a method according to the related art.

Referring to FIG. 1A, a line metal material is deposited on a semiconductor substrate 601 on which an NMOS or PMS transistor (not shown in the drawing) is formed. The line metal material is then patterned to form a lower line layer 603.

A USG (undoped silicate glass) oxide layer is deposited on the substrate 601 including the lower line layer 603 to form a first insulating interlayer 604.

A TEOS (tetraethyorthosilicate, Si(OCH₂CH₃)₃) or SiH₄ PEUSG (plasma enhanced undoped silicate glass) oxide layer is deposited on the first insulating interlayer 604 to form a second insulating interlayer 605.

In doing so, each of the first and second insulating interlayers 604 and 605 is not formed flat but has an indented surface topography due to the step difference of the lower line layer 603.

Referring to FIG. 1B, CMP (chemical mechanical polishing) is carried out on the second insulating interlayer 605 to planarize the first and second insulating interlayers 604 and 605. Yet, the CMP is insufficient for the planarization of the second insulating interlayer 605 and leaves a recess 670 due to over-polishing or dishing.

A via hole (not shown in the drawing) is formed by selectively etching the second and first insulating interlayers 605 and 604 overlapped with the lower line layer 603. The via hole is filled up with tungsten (W) to form a plug. A line metal layer is formed over the substrate including the plug and is then patterned to form an upper line layer brought into contact with the lower line layer 603 via the plug. Thus, the insulating layer between the upper and lower line layers is formed by forming the insulator of USG, d-TEOS, PE-SiH₄ or the like and by planarizing the insulator by CMP.

Referring to FIG. 1C, when the gap between metal lines is big, it is difficult to eliminate the step difference. Local planarization cannot be efficiently achieved. A metal line residue 606a thus accumulates in the recess to induce an inter-metal-line bridge.

The related art semiconductor device fabricating method has the problem of inducing an inter-metal-line bridge.

Additionally, the corresponding Cu line corrosion considerably degrades performance and reliability of the device.

### SUMMARY OF THE INVENTION

Accordingly, the present invention is directed to a method of fabricating a semiconductor device that substantially obviates one or more problems due to limitations and disadvantages of the related art.

An advantage of the present invention is that it provides a method of fabricating a semiconductor device, in which a defect due to an inter-metal-line bridge is prevented by effectively eliminating the step difference that is disadvantageous for local planarization after insulating layer planarization and by which throughput of the semiconductor device is raised by reducing leakage current and misalignment error generated from a subsequent process.

Additional advantages, and features of the invention will be set forth in part in the description which follows, and will become apparent from the description, or may be learned by practice of the invention. These and other advantages of the invention may be realized and attained by the structure particularly pointed out in the written description and claims hereof as well as the appended drawings.

To achieve these and other advantages and in accordance with the purpose of the invention, as embodied and broadly described herein, a method of fabricating a semiconductor device according to the present invention includes the steps of forming an insulating layer on a semiconductor substrate including a transistor, planarizing the insulating layer, and performing surface treatment on the planarized insulating layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiment(s) of the invention and together with the description serve to explain the principles of the invention. In the drawings:

FIGS. 1A to 1C are cross-sectional diagrams of a semiconductor device being fabricated in accordance with a method of the related art; and

FIGS. 2A to 2E are cross-sectional diagrams of a semiconductor device being fabricated by method in accordance with an exemplary embodiment of the present invention.

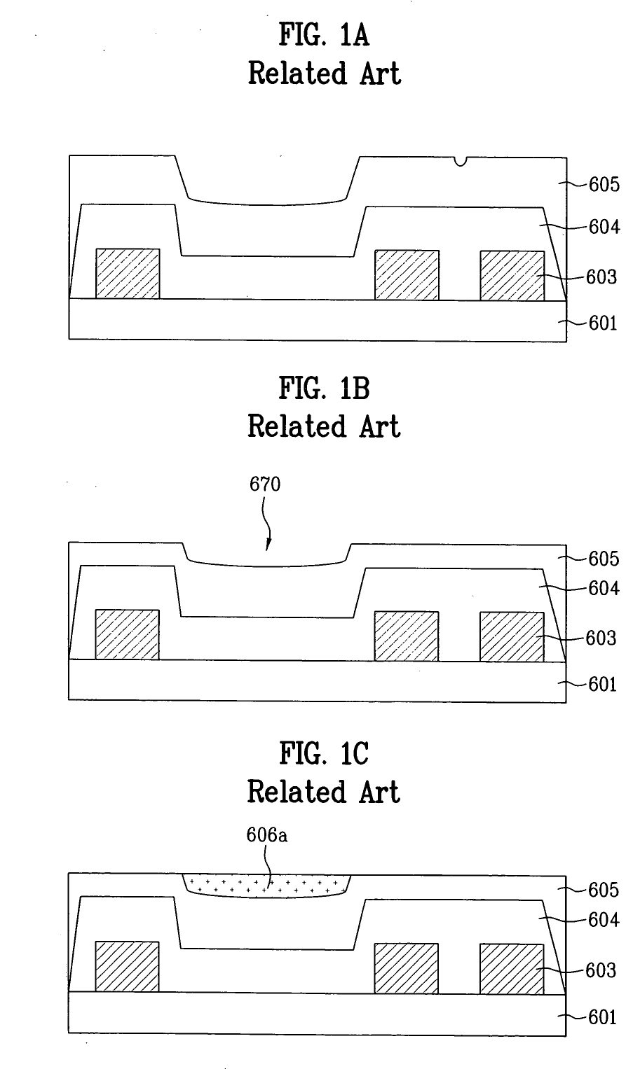

### DETAILED DESCRIPTION OF THE INVENTION

Reference will now be made in detail to exemplary embodiments of the present invention, examples of which are illustrated in the accompanying drawings. Wherever possible, the same reference numbers will be used throughout the drawings to refer to the same or like parts.

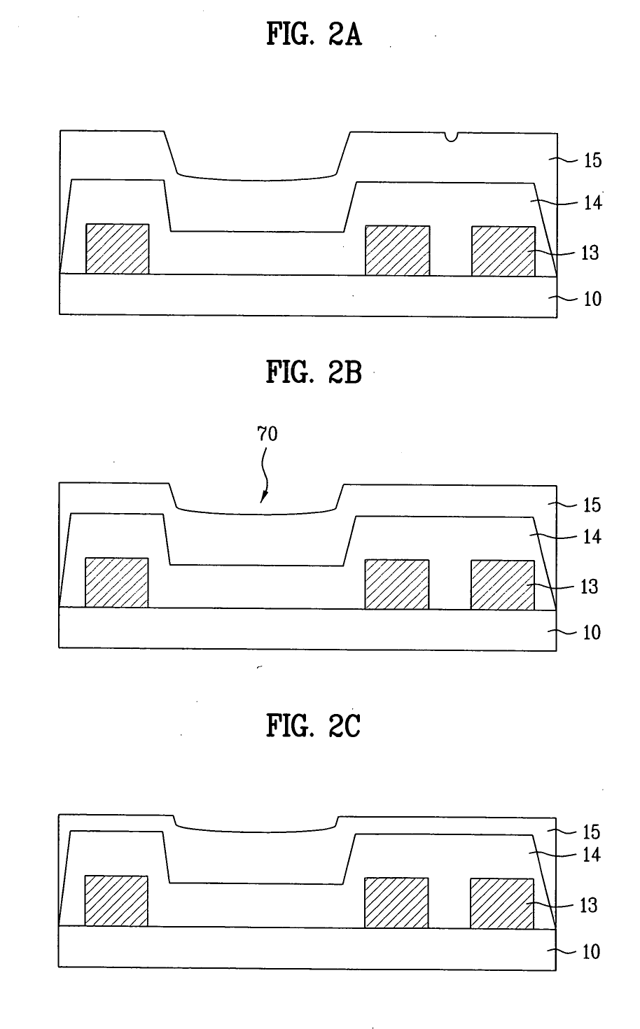

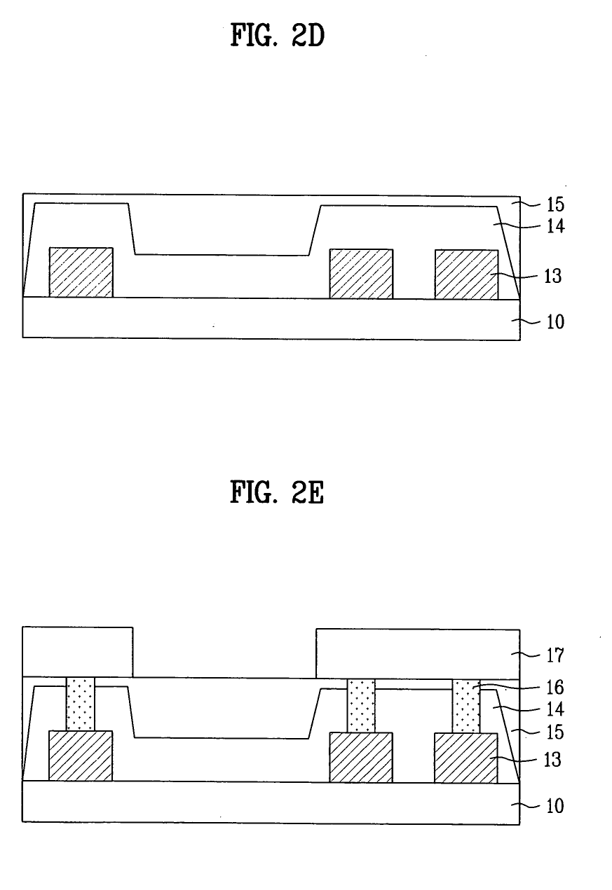

FIGS. 2A to 2E are cross-sectional diagrams of a semiconductor device being fabricated by a method in accordance with an exemplary embodiment of the present invention, in which a transistor and various elements are formed on a semiconductor substrate to fabricate a semiconductor device.

Referring to FIG. 2A, Cu is deposited on a semiconductor substrate 10 by sputtering and is then patterned to form a lower line layer 13 by photolithography.

A USG (undoped silicate glass) oxide layer is deposited on the semiconductor substrate 10 including the lower line layer 13 to form a first insulating interlayer 14.

A TEOS (tetraethyorthosilicate, Si(OCH₂CH₃)₃) or SiH₄ PEUSG (plasma enhanced undoped silicate glass) oxide layer is deposited on the first insulating interlayer 14 to form a second insulating interlayer 15. In doing so, each of the first and second insulating interlayers 14 and 15 is not formed flat but has an indented surface topography due to a step difference of the lower line layer 13.

Referring to FIG. 2B, CMP (chemical mechanical polishing) is carried out on the second insulating interlayer 15 to planarize the first and second insulating interlayers 14 and 15. Yet, the CMP is insufficient for the planarization of the second insulating interlayer 15 and leaves a recess 70 due to over-polishing or dishing.

Referring to FIG. 2C, DHF (diluted hydrofluoric acid) surface treatment is carried out to effectively eliminate the step difference. In particular, the DHF surface treatment is carried out by dipping the semiconductor device in a reaction vessel holding an approximately 100-200:1 mixed chemical solution of DI (deionized water) and HF after completion of CMP.

The profile of a surface of the insulating layer is varied by the DHF surface treatment to effectively eliminate the step difference disadvantageous for the local planarization. Hence, the problem of the inter-metal-line bridge can be solved.

Referring to FIG. 2D, buffing polishing is further carried out on the second insulating interlayer 15 after the DHP dipping treatment to completely planarize a surface of the insulating layer. Hence, the over-polished or dished area due to the insulating layer step difference may be completely eliminated.

Referring to FIG. 2E, a via hole (not shown in the drawing) is formed by selectively etching the second and first insulating interlayers 15 and 14 overlapped with the lower line layer 13 until a surface of the lower line layer 13 is exposed. The via hole is filled with tungsten (W) to form a plug 16. A line metal layer is formed over the substrate including the plug 16 and is then patterned to form an upper line layer 17 brought into contact with the lower line layer 13 via the plug 16. Alternatively, the plug 16 and the upper line layer 17 can be simultaneously formed by a dual damascene process.

Since the surface of the insulating layer is completely planarized, a tungsten residue is prevented from remaining on the insulating layer. Hence, the bridge problem between the upper line layers 17 can be solved.

Thus, the insulating layer between the upper and lower line layers is formed by forming the insulator of USG, d-TEOS, PE-SiH₄ or the like and by completely planarizing the insulator by CMP and DHP dipping treatment. Optionally, the buffing polishing can be further carried out after completion of the DHF dipping treatment.

The above-explained exemplary embodiment of the present invention is described with reference to the insulating layer between the metal lines. However, it is to be understood that the insulating layer planarizing method according to the present invention is applicable to all kinds of processes that need planarization. In particular, the present invention is applicable to PMD (premetal dielectric) planarization, IMD (intermetal dielectric) planarization, passivation layer planarization, etc.

Accordingly, the present invention provides the following effects.

The step difference of the insulating layer surface is effectively eliminated by DHF dipping treatment after completion of the insulating layer planarization, whereby the tungsten residue is prevented from remaining on the insulating layer surface. Hence, the problem of the inter-metal-layer bridge can be solved. Thus, by preventing the bridge, the present invention reduces the leakage current and the misalignment of a subsequent process, thereby raising throughput of the semiconductor device.

It will be apparent to those skilled in the art that various modifications and variations can be made in the present invention without departing from the spirit or scope of the inventions. Thus, it is intended that the present invention cover the modifications and variations of this invention provided they come within the scope of the appended claims and their equivalents.

What is claimed is:

1. A method of fabricating a semiconductor device, comprising the steps of:
forming an insulating layer on a semiconductor substrate including a transistor;
planarizing the insulating layer; and
performing surface treatment on the planarized insulating layer.

2. The method of claim 1, wherein the surface treatment of the insulating layer is performed using DHF (diluted hydrofluoric acid).

3. The method of claim 2, wherein the DHF includes DI (deionized water) and HF (fluoric acid) at a concentration ratio of about 100-200:1.

4. The method of claim 1, further comprising the step of performing buffing polishing on the insulating layer after completion of the surface treatment.

5. The method of claim 1, further comprising the steps of:
forming a first metal line on the semiconductor substrate prior to forming the insulating layer;
forming a via hole by selectively etching the surface-treated insulating layer until a surface of the first metal line is exposed;
forming a plug by filling the via hole with a conductive material; and
forming a second metal line on the insulating layer to be brought into contact with the plug.

6. The method of claim 5, wherein the conductive material is tungsten (W).

7. The method of claim 5, wherein the plug and the second metal line are simultaneously formed.

8. The method of claim 5, the insulating layer forming step comprising the steps of:
forming a first insulating layer on the semiconductor substrate; and
forming a second insulating layer on the first insulating layer.

9. The method of claim 8, wherein the first insulating layer is formed by depositing a USG (undoped silicate glass) oxide layer.

10. The method of claim 8, wherein the second insulating layer is formed by depositing a TEOS (tetraethyorthosilicate, Si(OCH₂CH₃)₃) or SiH₄ based PEUSG (plasma enhanced undoped silicate glass) oxide layer.

11. A method of fabricating a semiconductor device, comprising the steps of:
forming an insulating layer on a semiconductor substrate including a transistor;
planarizing the insulating layer;
performing a surface treatment using DHF on the planarized insulating layer; and
polishing the treated planarized insulating layer to obtain a surface substantially free of dishing.
